(19) United States
(12) Patent Application Publication
(10) Pub. No.: US 2026/0251682 A1
(43) Pub. Date: Aug. 27, 2026

(54) ELECTRICAL CONTACTOR AND METHOD OF MANUFACTURING ELECTRICAL CONTACTOR

(71) Applicant: KABUSHIKI KAISHA NIHON MICRONICS, Tokyo (JP)

(72) Inventor: TOMOAKI KUGA, Tokyo (JP)

(21) Appl. No.: 19/162,727

(22) PCT Filed: Mar. 19, 2024
(86) PCT No.: PCT/JP2024/010780

§ 371 Date: Sep. 5, 2025

(30) Foreign Application Priority Data
Mar. 23, 2023 (JP) 2023-046281

(51) Int. Cl. G01R 3/00; G01R 1/067

(52) U.S. Cl. CPC G01R 3/00; G01R 1/06716; G01R 1/06738

(57) ABSTRACT

To provide a method of manufacturing an electrical contactor including a volute spring structure extending in upward and downward directions formed integrally using a single material, having mechanical simplicity and excellent functionality, and functioning as an electric circuit achieving connection without loss. The present disclosure relates to a method of manufacturing an electrical contactor formed from a single rod-like conductive member of a circular cross section, the method comprising: a first step of forming a spiral slit with respect to an upper portion and/or a lower portion to be cylindrically formed of the rod-like member; a second step of winding up the upper portion and/or the lower portion of the rod-like member subjected to the slit formation performed by the first step so as to form a conical shape; and a third step of compressing a spiral structure of each hierarchy of the upper portion and/or the lower portion of the spiral rod-like member wound up by the second step until the spiral structure of each hierarchy overlaps with each other, and then performing a hardening heat treatment to form an electrical contactor including a spiral-structured elastic portion.

### TECHNICAL FIELD

The present disclosure relates to an electrical contactor and a method of manufacturing the electrical contactor, and is applicable, for example, to an electrical contactor used for a current-carrying test of an integrated circuit or inspection device on a semiconductor wafer, and a method of manufacturing the electrical contactor.

### BACKGROUND ART

Inspection devices, such as an integrated circuit formed on a semiconductor wafer and a packaged integrated circuit, are subjected to an inspection of electrical characteristics at each manufacturing stage. An electrical inspection of an integrated circuit on a semiconductor wafer is conducted using an electrical connecting apparatus such as a probe card, and an electrical inspection of a packaged integrated circuit is conducted using an electrical connecting apparatus such as a socket. In such an electrical connecting apparatus, an electrical contactor is used in contact with a first contact target and a second contact target, and an electrical signal is conducted between the first contact target and the second contact target through an electrical contactor.

Conventionally, there have been various types of electrical contactors, some of which are formed by combining a plurality of components. When such an electrical contactor formed of a plurality of components is used to conduct an electrical signal between the first contact target and the second contact target, resistance becomes large at a contact point between the components, thereby affecting electrical conductivity.

Patent Document 1 discloses a spring probe with a spiral and cylindrical sleeve, a first terminal at one end of the cylindrical sleeve, and second terminal at the other end of the cylindrical sleeve integrally molded by performing a bending process on a thin strip-shaped substrate. Such a spring probe is integrally formed from the thin strip-shaped substrate, thereby achieving favorable electrical conductivity.

### CITATION LIST

### Patent Literature

Patent Literature 1: Japanese Patent Application Laid-Open Publication No. 2011-012992
Patent Literature 2: Japanese Patent Application Laid-Open Publication No. 2021-188984

### SUMMARY OF INVENTION

### Technical Problem

However, when the electrical signal is conducted between the first contact target and the second contact target using the spring probe described in Patent Literature 1, an electrical conduction path in the spring probe passes through a pair of spirally wound coil springs, and therefore the path length becomes longer, which requires an improvement in the electrical conductivity.

In this regard, it is conceivable that a volute spring formed by spirally winding a plate-shaped member and covering a part of an inner member thereof with an outer member thereof is used as it is as an electrical contactor, for example.

Such an electrical contactor having a volute spring structure is formed by winding one plate-shaped member (single member), and thus it is possible to eliminate a contact point between constituent members. Therefore, it is possible to reduce a resistance value on a conduction path in the electrical contactor having the volute spring structure. It is also possible to shorten the path length of the conduction path in the electrical contactor having the volute spring structure, which is also expected to achieve favorable electrical conductivity.

However, a processing method of forming an electrical contactor having the volute spring structure by winding up (spirally winding) a single member has a problem of unstable production.

Accordingly, in view of the above-described problems, the present disclosure aims to provide an electrical contactor including a volute spring structure extending in upward and downward directions formed integrally using a single material, having mechanical simplicity and excellent functionality, and functioning as an electric circuit achieving connection without loss, and a method of manufacturing such an electrical contactor.

### Solution to Problem

A first aspect of the present disclosure relates to (1) a method of manufacturing an electrical contactor formed from a single rod-like conductive member of a circular cross section, the method including: (2) a first step of forming a spiral slit with respect to an upper portion and/or a lower portion to be cylindrically formed of the rod-like member; (3) a second step of winding up the upper portion and/or the lower portion of the rod-like member subjected to slit processing performed by the first step so as to form a conical shape; and (4) a third step of compressing a spiral structure of each hierarchy of the upper portion and/or the lower portion of the spiral rod-like member wound up by the second step until the spiral structure of each hierarchy overlaps with each other, and then performing a hardening heat treatment to form an electrical contactor including a spiral-structured elastic portion.

A second aspect of the present disclosure relates to an electrical contactor formed from a single rod-like conductive member of a circular cross section, the electrical contactor including: (1) one or two elastic portions formed by forming a spiral slit with respect to an upper portion and/or a lower portion to be cylindrically formed of the rod-like member, winding up the upper portion and/or the lower portion of the rod-like member subjected to the slit formation so as to form a conical shape, compressing the spiral structure of each hierarchy of the wounded portion until the spiral structure of each hierarchy overlaps with each other, and performing a hardening heat treatment; and (2) a center portion which is the rod-like member itself.

A third aspect of the present disclosure relates to an electrical contactor formed from a single rod-like conductive member of a circular cross section, the electrical contactor including: (1) one or two spiral-structured elastic portions formed at an upper portion or a lower portion thereof; and (2) a center portion which is the rod-like member itself, wherein (3) the elastic portion is formed so that each spiral-structured hierarchy overlaps with each other and one end of the elastic portion includes a contact portion that is in contact with a contact target.

### Advantageous Effects of Invention

According to the present disclosure, it is possible to provide an electrical contactor including a volute spring structure extending in upward and downward directions formed integrally using a single material, having mechanical simplicity and excellent functionality, and functioning as an electric circuit achieving connection without loss, and a method of manufacturing the electrical contactor.

### BRIEF DESCRIPTION OF DRAWINGS

FIG. 1 is a configuration diagram illustrating a configuration of a connector according to an embodiment.

FIG. 2 is a configuration diagram illustrating a configuration of an electrical connecting apparatus according to the embodiment.

FIG. 3 is an explanatory diagram illustrating an outline of a process of forming the connector according to the embodiment.

FIG. 4 is an explanatory diagram illustrating a configuration of a process of forming the connector according to the embodiment.

FIG. 5 is a configuration diagram illustrating a configuration of a connector according to a modified embodiment (first aspect).

FIG. 6 is a configuration diagram illustrating a configuration of a connector according to the modified embodiment (second aspect).

FIG. 7 is a configuration diagram illustrating a configuration of a connector according to the modified embodiment (third aspect).

FIG. 8 is a configuration diagram illustrating a configuration of a connector according to the modified embodiment (fourth aspect).

FIG. 9 is a configuration diagram illustrating a configuration of a connector according to the modified embodiment (fifth aspect).

FIG. 10 is a configuration diagram illustrating a configuration of a connector according to the modified embodiment (sixth aspect).

FIG. 11 is an explanatory diagram illustrating a housing state of the connector according to the embodiment.

### DESCRIPTION OF EMBODIMENTS

### (A) Principal Embodiment

Hereinafter, this embodiment of an electrical contactor and a method of manufacturing the electrical contactor according to the present disclosure will be described in detail, with reference to the drawings.

This embodiment illustrates a case where the electrical contactor according to the present disclosure is applied to a connector to be mounted on an electrical connection unit, which is a constituent member of the electrical connecting apparatus, as will be described later. The electrical contactor according to the present disclosure can be applied to any contactor configured to electrically contact a first contact target and a second contact target and capable of conducting an electrical signal between the first contact target and the second contact target. While this embodiment illustrates the case where the electrical contactor of the present disclosure is applied to the connector of the electrical connecting unit, the present disclosure can also be applied to a probe or the like configured to be connected to an electrode terminal of an inspection device.

Moreover, this embodiment illustrates a case where the electrical connecting apparatus according to the present disclosure is an electrical connecting apparatus used for an electrical inspection of an inspection device, which is an integrated circuit formed on a semiconductor wafer. The electrical connecting apparatus according to the present disclosure can be applied to an apparatus configured to conduct the electrical signal between the first contact target and the second contact target using the electrical contactor according to the present disclosure to be electrically connected therebetween.

### (A-1) Configuration of Embodiment

### (A-1-1) Electrical Connecting Apparatus

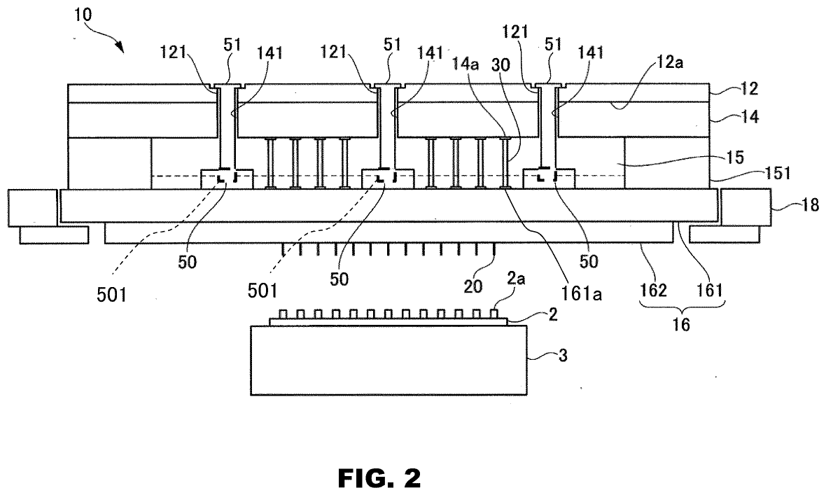

FIG. 2 is a configuration diagram illustrating a configuration of an electrical connecting apparatus according to the embodiment.

While FIG. 2 illustrates principal constituent members of the electrical connecting apparatus 10, the electrical connecting apparatus 10 is not limited to these constituent members but may actually also include constituent members not illustrated in FIG. 2. In the following description, the terms “upper” or “upward” and “lower” or “downward” will be mentioned with reference to the up-and-down direction in FIG. 2.

In FIG. 2, the electrical connecting apparatus 10 according to this embodiment includes a plate-shaped support member 12, a plate-shaped wiring board 14 held on a lower surface 12a of the supporting member 12, an electrical connecting unit 15 electrically connected to the wiring board 14, and a probe substrate 16 electrically connected to the electrical connecting unit 15 and including a plurality of probes 20.

A large number of fixation members (e.g., screwing members, such as bolts) are used to assemble the supporting member 12, the wiring board 14, the electrical connecting unit 15, and the probe substrate 16, into the electrical connecting apparatus 10, but such fixation members are not illustrated in FIG. 2.

The electrical connecting apparatus 10 conducts an electrical inspection on an inspection device 2, in which a semiconductor integrated circuit or the like formed on a semiconductor wafer is used as the inspection device 2, for example. Specifically, the inspection device 2 is electrically inspected by pressing the inspection device 2 toward the probe substrate 16, electrically contacting a tip portion of each probe 20 of the probe substrate 16 with each electrode terminal 2a of the inspection device 2, and supplying an electrical signal to the electrode terminal 2a of the inspection device 2 from a tester (inspection apparatus), which is not illustrated, and further providing an electrical signal from the electrode terminal 2a of the inspection device 2 to the tester side.

The inspection device 2, which is to be inspected, is placed on an upper surface of a chuck top 3. The chuck top 3 is capable of adjusting a position in an X-axial direction in a horizontal direction, a Y-axial direction perpendicular to the X-axial direction on a horizontal plane, and a Z-axial direction perpendicular to the horizontal plane (X-Y plane), and is further capable of adjusting a rotational posture in a θ direction around the Z axis. For implementation of an electrical inspection on the inspection device 2, a chuck capable of moving in an up-and-down direction (Z-axial direction) is moved so that each electrode terminal 2a of the inspection device 2 is electrically contacted with the tip portion of each probe 20 of the probe substrate 16. For this purpose, the lower surface of the probe substrate 16 of the electrical connecting apparatus 10 and the inspection device 2 placed on the upper surface of the chuck top 3 are moved to be relatively closer to each other.

[supporting Member]

The supporting member 12 suppresses deformation (e.g., bending or the like) of the wiring board 14. For example, since the probe substrate 16 has a large number of the probes 20, a weight of the probe substrate 16 attached to the wiring board 14 side is increased. Moreover, when conducting the electrical inspection on the inspection device 2, the probe substrate 16 is pressed against the inspection device 2 placed on the chuck top 3 such that between the tip portion of each probe 20 protruding from the lower surface of the probe substrate 16 is electrically contacted with each electrode terminal 2a of the inspection device 2. Thus, during the electrical inspection, a large load is applied also to the wiring board 14 due to action of a reaction force (contact load) pushed upward from below. The supporting member 12 functions as a member for suppressing deformation (e.g., bending or the like) of the wiring board 14.

Moreover, a plurality of through holes 121 are provided in the supporting member 12 so as to pass through between the upper surface and the lower surface thereof. Each of the plurality of through holes 121 is provided at a position corresponding to a plurality of anchors 50 disposed on the upper surface of the probe substrate 16 described below, which is a position corresponding to each of a plurality of through holes 141 provided in the wiring board 14.

A spacer (hereinafter, also referred to as a “supporter”) 51 is inserted into each through hole 121 of the supporting member 12 downward from above the supporting member 12, and is configured such that a lower end portion of the spacer (supporter) 51 can be fixed to the corresponding anchor 50. For example, the lower end portion of the spacer (supporter) 51 is a male screw portion, and a substantially center portion of the anchor 50 disposed on the upper surface of the probe substrate 16 is a female screw portion 501. The fixing can be achieved by screwing the lower end portion (male screw portion) of the spacer (supporter) 51 into the female screw portion of the anchor 50. Consequently, it is possible to maintain a distance between the upper surface of the probe substrate 16 and the upper surface of the supporting member 12 at a predetermined distance length.

### [Wiring Board]

The wiring board 14 is, for example, a substantially plate-shaped printed board or the like formed with a resin material such as polyimide, for example. A large number of electrode terminals (not illustrated) to be electrically connected to a test head (not illustrated) of a tester (inspection apparatus) are disposed in a peripheral edge of an upper surface of the wiring board 14. Moreover, a wiring pattern is formed on the lower surface of the wiring board 14, and a connecting terminal 14a of the wiring pattern is electrically connected to an upper end portion of the connector 30 provided in the electrical connecting unit 15.

Furthermore, a wiring circuit (not illustrated) is formed inside the wiring board 14, and the wiring pattern formed on the lower surface of the wiring board 14 and the electrode terminal formed on the upper surface of the wiring board 14 can be connected to each other through the wiring circuit formed inside the wiring board 14. Accordingly, it is possible to conduct an electrical signal through the wiring circuit in the wiring board 14 between each connector 30 of the electrical connecting unit 15, which is to be electrically connected to the connecting terminal 14a of the wiring pattern formed on the lower surface of the wiring board 14, and the test head, which is to be connected to the electrode terminal formed on the upper surface of the wiring board 14. A plurality of electronic components required for the electrical inspection conducted on the inspection device 2 are also disposed on the upper surface of the wiring board 14.

Moreover, the plurality of through holes 141 are provided in the wiring board 14 so as to pass through between the upper surface and the lower surface of the wiring board 14. Each of the plurality of through holes 141 is provided at a position corresponding to a plurality of anchors 50 disposed on the upper surface of the probe substrate 16 described below, which is a position corresponding to each of a plurality of through holes 121 provided in the supporting member 12.

Each through hole 141 has an opening shape that can be determined in accordance with a shape of the supporter 51 to be inserted thereinto. Moreover, in order to allow each supporter 51 to be inserted into each through hole 141, an inner diameter of each through hole 141 is approximately equal to or slightly larger than an outer diameter of each supporter 51.

This embodiment illustrates a case where the opening shape of the through hole 141 is a substantially circular shape in order to illustrate a case where the supporter 51 is a circular columnar member, but the opening shape thereof is not limited to this example. For example, the supporter 51 may be a right prism member having a substantially square cross-sectional shape, a polygonal prism member having a polygonal cross-sectional shape, or the like, and even in such cases, the opening shape of the through hole 141 may be a shape that can be inserted into the supporter 51.

### [Electrical Connection Unit]

The electrical connecting unit 15 has a plurality of connectors 30. In an assembled state of the electrical connecting apparatus 10, an upper end portion of each connector 30 is electrically connected to each connecting terminal 14a of the wiring pattern formed on the lower surface of the wiring board 14, and a lower end portion of each connector 30 is connected to each pad provided on the upper surface of the probe substrate 16. The tip portion of the probe 20 is electrically contacted to the electrode terminal of the inspection device 2, and the electrode terminal of the inspection device 2 is electrically connected to the tester (inspection apparatus) through the probe 20 and the connector 30, and thus it is possible to electrically inspect the inspection device 2 with the tester (inspection apparatus).

For example, the electrical connecting unit 15 has a plurality of insertion holes for inserting the connectors 30 thereinto, respectively, and the upper end portion and the lower end portion of each connector 30 protrude therefrom by inserting each connector 30 into each insertion hole. In the electrical connecting unit 15, a mechanism of attaching the plurality of connectors 30 is not limited to the configuration of providing the through holes, and various configurations can be widely applied. A flange 151 is provided around a periphery of the electrical connection unit 15.

### [Probe Board]

The probe board 16 is a board including a plurality of probes 20 provided thereon and is formed into a substantially circular shape or a polygonal shape (e.g., hexadecagon or the like). The probe 20 may be, for example, but is not limited to, a cantilever type probe. Moreover, the probe substrate 16 has a substrate member 161 formed, for example, of a ceramic plate, and a multilayer wiring substrate 162 formed on a lower surface of the substrate member 161.

A large number of electrical conduction paths (not illustrated) passing through in a plate thickness direction are formed inside the substrate member 161, which is a ceramic substrate, a pad 161a is formed on the upper surface of the substrate member 161, and one end of the electrical conduction path in the substrate member 161 is formed so as to be connected to the corresponding pad 161a formed on the upper surface of the substrate member 161. Furthermore, on the lower surface of the substrate member 161, the other end of the electrical conduction path in the substrate member 161 is formed so as to be connected to the connecting terminal provided on the upper surface of the multilayer wiring substrate 162.

The multilayer wiring substrate 162 is formed of a plurality of multilayer substrates formed, for example, of a synthetic resin member such as polyimide, and a wiring path (not illustrated) is formed between the plurality of multilayer substrates. One end of the wiring path in the multilayer wiring substrate 162 is connected to the other end of the electrical conduction path on the substrate member 161 side, which is a ceramic substrate, and the other end of the multilayer wiring substrate 162 is connected to a probe land provided on the lower surface of the multilayer wiring substrate 162. The plurality of probes 20 are disposed on the probe land provided on the lower surface of the multilayer wiring substrate 162, and the plurality of probes 20 of the probe substrate 16 are respectively electrically connected to the corresponding connecting terminals 14a of the wiring board 14 through the electrical connecting unit 15.

### (A-1-2) Connector (Electrical Contactor)

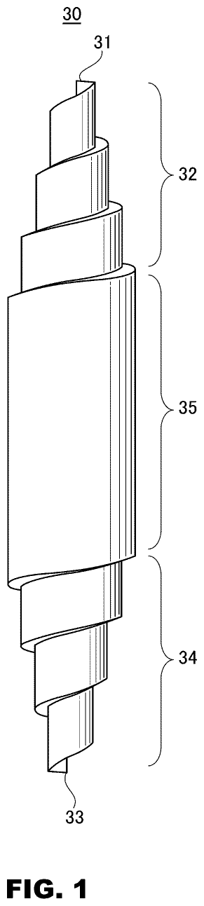

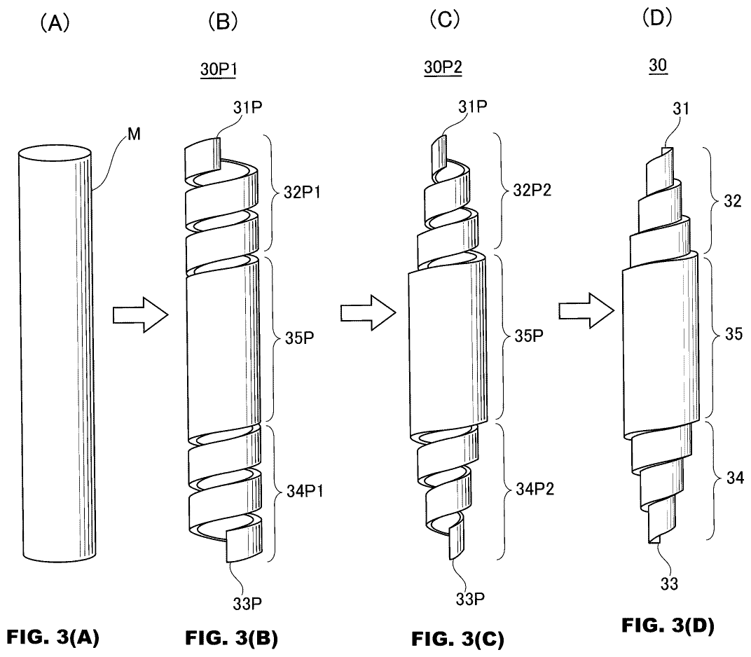

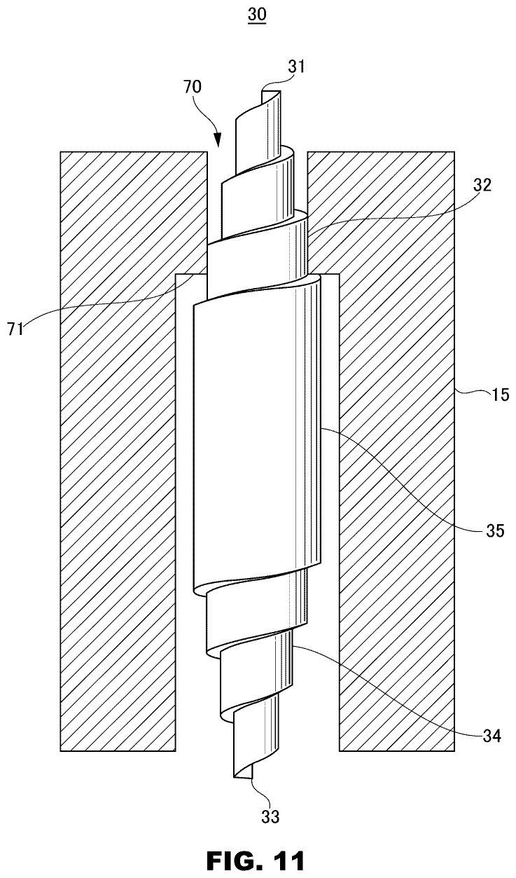

FIG. 1 is a configuration diagram illustrating a configuration of a connector according to an embodiment. FIG. 3 is an explanatory diagram illustrating an outline of a process of forming the connector according to the embodiment. Furthermore, FIG. 11 is an explanatory diagram illustrating a housing state of the connector according to the embodiment.

As illustrated in FIG. 1, the connector 30, which is an example of the electrical contactor, includes a first contact portion 31 in contact with the connecting terminal 14a of the wiring board 14 as a first contact target, an upper elastic portion 32 having an volute spring structure in an upward direction that elastically urges in upward and downward directions when the first contact portion 31 is in contact with the connection terminal 14a and receives a load, a second contact portion 33 in contact with the pad 161a of the substrate member 161 as a second contact target, a lower elastic portion 34 having a volute spring structure in a downward direction that elastically urges in the upward and downward directions when the second contact portion 33 is in contact with the pad 161a and receives a load, and a center portion 35 that connects the upper elastic portion 32 and the lower elastic portion 34.

In the example illustrated in FIG. 11, a through hole 70 for inserting the connector 30 is provided in the electrical connecting unit 15, and the connector 30 is inserted into the through hole 70. The inner diameter of a lower portion of the through hole 70 is slightly larger than or approximately equal to the outer diameter of the center portion 35. Moreover, an upper portion of the through hole 70 is smaller than the inner diameter of the lower portion of the through hole 70, and a stepped portion 71 is formed on an inner surface of the through hole 70. An upper portion of the center portion 35 of the connector 30 inserted is caught on the stepped portion 71 on the inner surface of the through hole 70. That is, the center portion 35 has an effect as a spring retainer even during the contact operation. Alternatively, the stepped portion 71 may be formed so that a lower portion of the center portion 35 may be caught. In any case, since the outer diameter of the center portion 35 is larger than the outer diameters of the upper elastic portion 32 and the lower elastic portion 34, the shape (stepped portion) of the through hole 70 can be used as the spring retainer even during the contact operation.

The first contact portion 31 has a tip end surface in contact with the first contact target, and the aforementioned tip end surface extends upward. The second contact portion 33 has a tip end surface in contact with the second contact target, and the aforementioned tip end surface extends downward. Shapes of the first contact portion 31 and the second contact portion 33 are not particularly limited and may be formed by various processing processes.

As an outline in each step in a method of manufacturing the connector 30 illustrated in FIG. 1, a portion of cylindrical pipe material M is subjected a molding process (slit formation) as illustrated in FIG. 3(A) to form a connector 30P1 as illustrated in FIG. 3(B), and then the slit-formed portion is wound up into a conical shape to form a connector 30P2 as illustrated in FIG. 3(C), and then a connector 30 having an intended shape (volute spring structure in the upward and downward directions) is formed as illustrated in FIG. 3(D) using compression and hardening treatments described below.

The pipe material M illustrated in FIG. 3 is a member before the molding process of the connector 30 illustrated in FIG. 1 (the connector 30P1, and the connector 30P2) and is a cylindrical rod-like member (cylindrical member) over the total length thereof formed of a conductive material. Namely, the connector 30 is formed from a single cylindrical member through the plurality of steps to form a structure in which it is overlapped and spirally wound up in a volute pattern (volute structure extending in the upward and downward directions), thereby stabilizing the conductivity of an electrical signal. In other words, in an electrical contactor formed by combining a plurality of components, an electrical signal is to be conducted by causing these components to be in contact with each other. This increases a resistance at a point of contact between these components, so that conduction performance may become unstable. In contrast, the connector 30 obtained by molding the single cylindrical member has no contact point between components, thereby making it possible to reduce the resistance value and to stabilize the conductivity of the electrical signal.

Moreover, since the connector 30 has the volute-shaped elastic body in the upward and downward directions, it is possible to reliably ensure the contact between the first contact target and the second contact target. Therefore, a connector 30 according to the present embodiment produces more advantageous effects than a connector having a volute-shaped elastic body in only one direction.

Various types of cylindrical members, such as cylindrical members made of precious metal or metal having electrical conductivity, are applicable to the pipe material M illustrated in FIG. 3(A). For example, a precipitation-hardened copper alloy such as Cu—Be based alloy (beryllium copper) is preferred as a material having high spring performance. The precipitation-hardened copper alloy is prepared by performing aging treatment on a solution-treated supersaturated solid solution. As a result, fine precipitates are uniformly dispersed to increase a strength of the alloy, while the content of a solid solution element in copper is reduced to improve electrical conductivity. Moreover, a palladium alloy is preferred as the pipe material M, as is the precipitation-hardened copper alloy.

The connector 30P1 illustrated in FIG. 3(B) is a connector formed by slitting a portion of the pipe material M. The connector 30P1 includes a structure corresponding to each structure part of the connector 30 described above. That is, as illustrated in FIG. 3(B), the connector 30P1 includes a first contact portion 31P, an upper elastic portion 32P1, a second contact portion 33P, a lower elastic portion 34P1, and a center portion 35P connecting the upper elastic portion 32P1 and the lower elastic portion 34P1.

Moreover, the connector 30P2 illustrated in FIG. 3(C) is a connector formed by winding up the slit-formed portions (the upper elastic portion 32P1 and the lower elastic portion 34P1) of the connector 30P1 until each of them becomes a conical-shape. The connector 30P2 also includes a structure corresponding to each structure part of the connectors 30, 30P1 described above. That is, as illustrated in FIG. 3(C), the connector 30P2 includes a first contact portion 31P, an upper elastic portion 32P2, a second contact portion 33P, a lower elastic portion 34P2, and a center portion 35P connecting the upper elastic portion 32P2 and the lower elastic portion 34P2.

The connector 30 and the connector 30P2 differ from each other in that, while the connector 30P1 has a volute structure formed by winding the a portion of pipe material M (the upper elastic portion 32, the lower elastic portion 34) into a spiral pattern and covering a part of a wound inner member with an outer member, the connector 30P2 has a barrel shape formed by winding the pipe material M into a spiral pattern without generating an overlap in the pipe material M.

According to the embodiment, in order to form the connector 30 having the intended shape (volute structure extending in the upward and downward directions), a portion of pipe material M illustrated in FIG. 3(A) is first subjected to the slit formation to form the connector 30P1, and then the slit-formed portion is wound up to form the connector 30P2, and then the connector 30 illustrated in FIG. 3(D) is formed using the compression and hardening treatment described below. Hereinafter, a method of manufacturing the connector 30 will be described.

### [Method of Manufacturing Connector]

### <Slit Formation>

First, as a procedure of manufacturing the connector 30, a portion of the rod-shaped pipe material M is subjected to slit formation using an already-existing techniques, such as a laser processing, to form the connector 30P1.

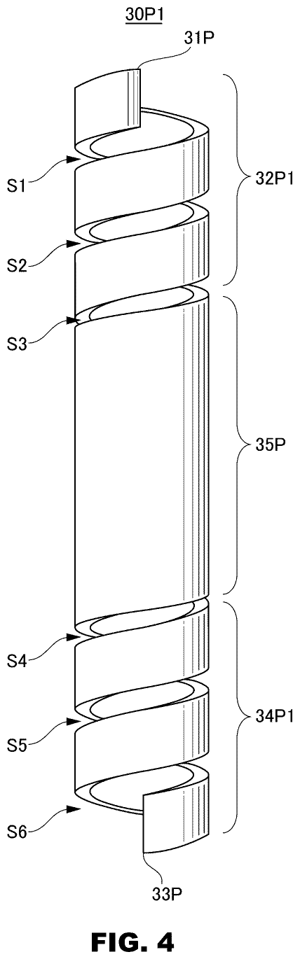

The pipe material M (the upper portion and the lower portion of the pipe material M) is subjected the slit formation, and thereby spiral slits S1 to S6 are formed in the connector 30P1 as illustrated in FIG. 4. In FIG. 4, for the purpose of illustrating the drawing, an example is illustrated in which the slits (gaps) are exaggerated in size to enable the slit (gaps) width to be easily recognized, but it is not particularly limited how the spiral slit structure is formed by the laser processing or the like.

The center portion 35P of the connector 30P1 remains in the pipe material M since no slit processing is applied thereto. That is, the center portion 35P of the connector 30P1 has high rigidity.

### <Narrowing and Winding Process>

Next, with the connector 30P1 fixed, the first contact portion 31P (tip portion) is contracted while narrowing and winding around an axis of the pipe material M, thereby forming the upper elastic portion. Similarly, the second contact portion 33P (tip portion) is contracted while narrowing and winding around the axis of the pipe material M, thereby forming the lower elastic portion.

FIG. 3(C) illustrates the connector 30P2 having the upper elastic portion 32P2 and the lower elastic portion 34P2 that are elastic portions in the state where the narrowing and winding process has been applied. In this state, each elastic section is in a slack state with no vertical overlap.

In this embodiment, the connector 30P2 (the upper elastic portion 32P2 and the lower elastic portion 34P2) forms a vertically symmetrical spiral structure via the center portion 35P, but the upper elastic portion 32P2 and the lower elastic portion 34P2 do not necessarily have to be formed with a vertically symmetrical spiral structure (i.e., they may be formed with an asymmetrical spiral structure).

### <Compression and Hardening Heat Treatment>

Next, the upper elastic portion 32P2 and the lower elastic portion 34P2 of the connector 30P2 are subjected to a hardening heat treatment in a state while being compressed so as to overlap upward and downward (i.e., a state of being compressed so as to be a volute structure), as illustrated in FIG. 3 (D). As a specific method for the compression and hardening heat treatment, for example, the technique described in Patent Literature 2 can be applied.

### (A-2) Advantageous Effects of Embodiment

As described above, according to the present embodiment, it becomes possible to solve processing constraints on formation into a volute spring structure by lap winding in a spiral pattern. That is, the portion of pipe materials is spirally slitted, and then the slit-formed portion is narrowed and wound and then compressed and hardened, and thereby it is possible to form the intended shape (volute structure).

The electrical contactor (connector) of the present embodiment manufactured by the foregoing manufacturing method has a volute spring structure extending in the upward and downward directions and formed integrally using a single material. This allows the electrical contactor to have mechanical simplicity and excellent functionality (improvement in slidability due to the single member), and to function as an electric circuit achieving connection without loss.

Moreover, the connector 30 manufactured by the pipe slit forming method of the present manufacturing method has a main body (center portion 35) that remains the pipe material M and therefore has high rigidity. Furthermore, the pipe slit forming method of the present manufacturing method has an advantage that the total spring length can be easily set.

### (B) Other Embodiments

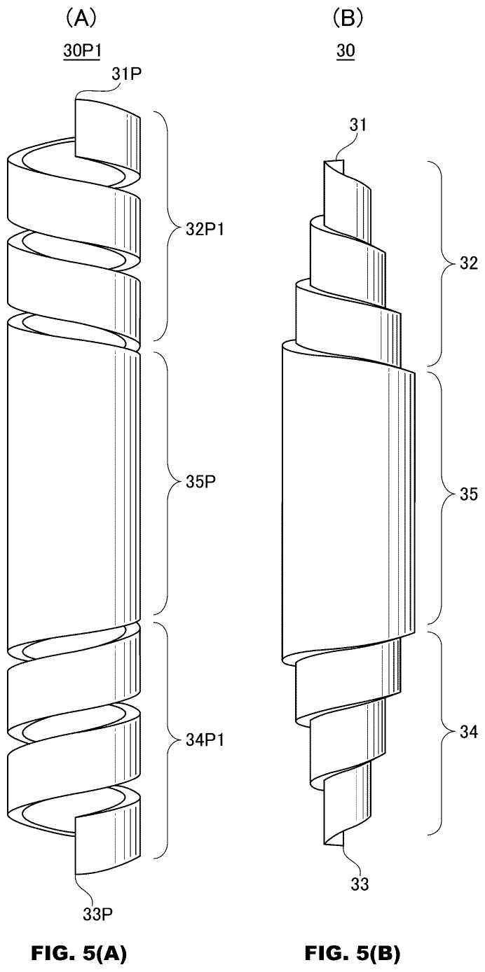

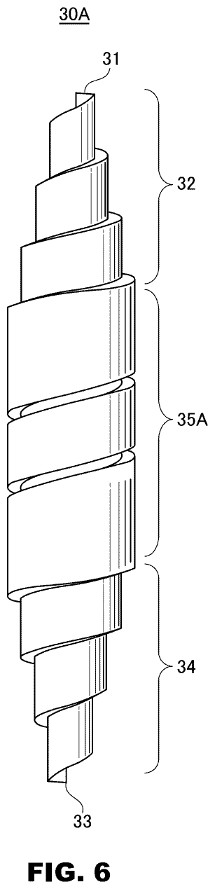

Although the modified embodiments have been described in the above-described embodiment, the present disclosure can also be applied to the following modified embodiments.
(B-1) The spiral winding direction (one-sided winding direction) of the slit-formed portion by the above-mentioned pipe slit forming method is not particularly limited. For example, as illustrated in FIG. 5, the spiral winding direction may be reversed to that of the above-described embodiment (FIG. 5(A)), and the connector 30 (FIG. 5(B)) may be manufactured by the compression and hardening treatment.
(B-2) In the above-mentioned embodiment, no slits are formed in the body portion (center portion 35) of the connector 30, but slits may be formed therein illustrated in FIG. 6. In a connector 30A of FIG. 6, by forming a slit (e.g., an independent spiral slit that is not continuous with the slits of the upper and lower elastic portions) in a center portion 35A, the stroke and load can be controlled in conjunction with the upper and lower spiral springs (the upper elastic portion 32 and the lower elastic portion 34).

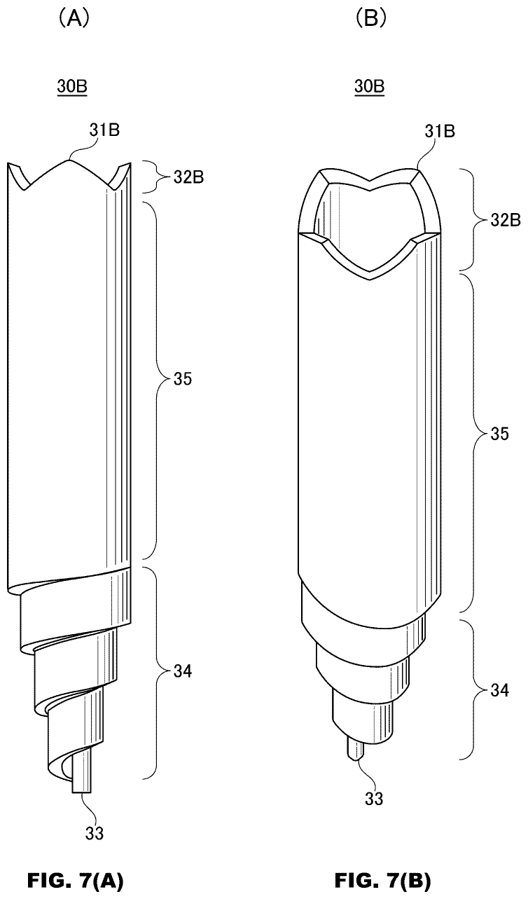

(B-3) In the above-mentioned embodiment, the upper elastic portion 32 and the lower elastic portion 34 of the connector 30 both have a spirally wound structure (volute structure), but any one thereof may have a different shape. For example, in a connector 30B illustrated in FIG. 7, an upper elastic portion 32B has a crown shape. FIG. 7(A) is a diagram illustrating the connector 30B as viewed from the side, and FIG. 7(B) is a diagram illustrating the connector 30B as viewed from directly above. The crown type has four tip portions (first contact portions 31B) and therefore has excellent contact with the electrode pad.

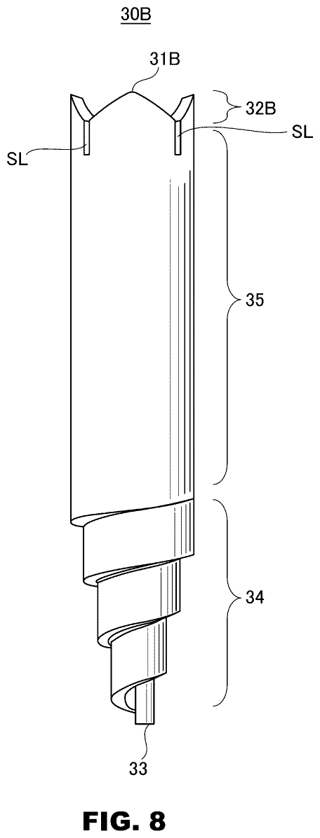

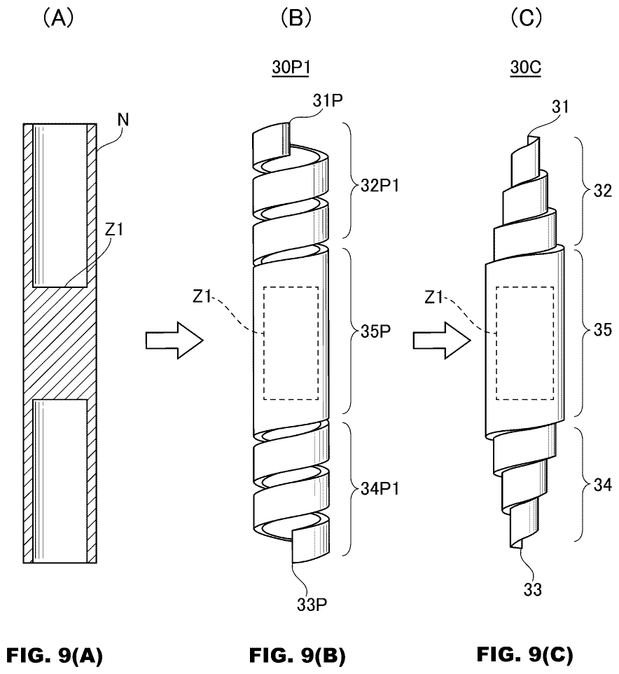

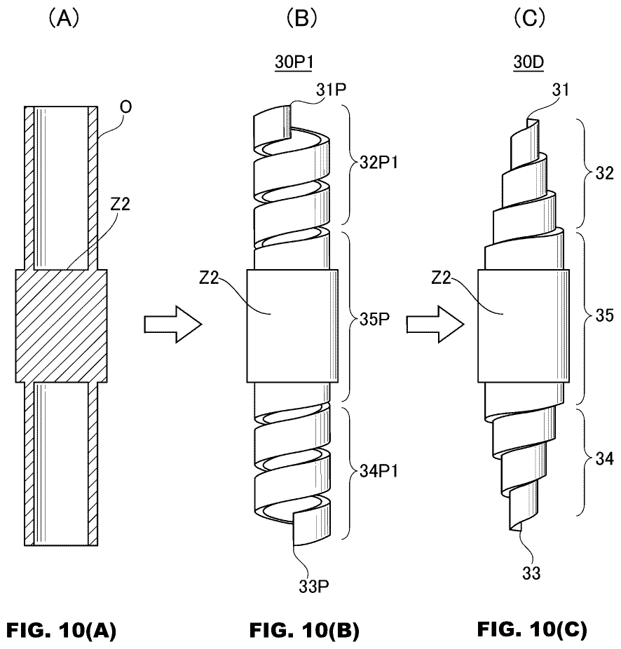

Alternatively, as illustrated in FIG. 8, the crown (upper elastic portions 32) of the connector 30B may have slits directly below each bottom portion (it may be formed in all four places or in less than four places). By forming the slits, each structure (polygon) including the first contact portion 31 can be spread laterally while making contact. Depending on a specification of the electrode pad, it may be better for the crown to deform in this manner. In any case, there is no particular limitation on the shape of the upper elastic portion 32 (or the lower elastic portion 34).
(B-4) In the above-mentioned embodiment, the connector 30 is manufactured from a rod-shaped pipe material M that is cylindrical over its total length, but as illustrated in FIG. 9, the connector 30C may also be manufactured from a rod-shaped member N formed by countersinking both ends of a cylindrical rod-shaped pipe material, as in the same procedure as that of the above-mentioned embodiment, i.e., by applying the slit formation, and the compressing and hardening heat treatment to the upper and lower portions that have been made cylindrical by the countersinking. The appearance of the connector 30C is the same as that of the connector 30, but the inside of the center portion 35 (center portion Z1) has a solid structure, which makes it electrically advantageous compared with the connector 30 manufactured from the pipe material M. Similarly, the rigidity of the center portion 35 of the connector 30C is higher than that of the connector 30.
(B-5) Alternatively, as illustrated in FIG. 10, a connector 30D may be manufactured from a rod-shaped member O having a center portion Z2 in which an outer circumferential surface is convex over the entire circumference in addition to being countersunk, by the same procedure as that of the above-mentioned embodiment. In addition to the electrical superiority and improved rigidity of the connector 30C mentioned above, the connector 30D has a convex center portion 35 (center portion Z2) and thus produces the effect of spring retainer during contact operation.
(B-6) In the above-mentioned embodiment, slit formation is used to realize the spiral structure of the upper elastic portion 32 and the lower elastic portion 34 of the connector 30, but the present disclosure is not limited to such an example. For example, etching techniques used for producing Micro Electro Mechanical Systems (MEMS) may be applied.
(B-7) The above-mentioned embodiment illustrates an example of manufacturing the spiral-structured spring from a cylindrical or circular columnar pipe material M (rod-shaped member), but the materials are not limited to these rod-shaped metal members, and metals of various shapes (e.g., rectangular) may be used.

### REFERENCE SIGNS LIST

30, 30A, 30B, 30C, 30D, 30P1, 30P2: Connector;
31, 31B, 31P: First contact portion;
32, 32B, 32P1, 32P2: Upper elastic portion;
33, 33P: Second contact portion;
34, 34P1, 34P2: Lower elastic portion;
35, 35A, 35P: Center portion;
70: Through hole;
71: Stepped portion;

M: Pipe material;
N, O: Rod-like member; and
S1 to S6: Slit.

1. A method of manufacturing an electrical contactor, the electrical contactor formed from a single rod-like conductive member of a circular cross section, the method comprising:
a first step of forming a spiral slit with respect to an upper portion and/or a lower portion to be cylindrically formed of the rod-like member;
a second step of winding up the upper portion and/or the lower portion of the rod-like member subjected to the slit formation performed by the first step so as to form a conical shape; and
a third step of compressing a spiral structure of each hierarchy of the upper portion and/or the lower portion of the spiral rod-like member wound up by the second step until the spiral structure of each hierarchy overlaps with each other, and then performing a hardening heat treatment to form an electrical contactor including a spiral-structured elastic portion.

2. The method of manufacturing the electrical contactor according to claim 1, wherein in the first step, the spiral slit is formed by laser processing.

3. The method of manufacturing the electrical contactor according to claim 1, wherein an end surface of the upper portion or the lower portion of the rod-like member is crown-shaped.

4. The method of manufacturing the electrical contactor according to claim 1, wherein another slit, which is independent from the slit, is formed also in a center portion of the rod-like member.

5. An electrical contactor formed from a single rod-like conductive member of a circular cross section, the electrical contactor comprising:
one or two elastic portions formed by forming a spiral slit with respect to an upper portion and/or a lower portion to be cylindrically formed of the rod-like member, winding up the upper portion and/or the lower portion of the rod-like member subjected to the slit formation so as to form a conical shape, compressing the spiral structure of each hierarchy of the wounded portion until the spiral structure of each hierarchy overlaps with each other, and performing a hardening heat treatment; and
a center portion which is the rod-like member itself.

6. An electrical contactor formed from a single rod-like conductive member of a circular cross section, the electrical contactor comprising:
one or two spiral-structured elastic portions formed at an upper portion or a lower portion of the rod-like member; and
a center portion which is the rod-like member itself, wherein
the elastic portion is formed so that each spiral-structured hierarchy overlaps with each other and one end of the elastic portion includes a contact portion that is in contact with a contact target.

7. The method of manufacturing the electrical contactor according to claim 2, wherein an end surface of the upper portion or the lower portion of the rod-like member is crown-shaped.

8. The method of manufacturing the electrical contactor according to claim 2, wherein another slit, which is independent from the slit, is formed also in a center portion of the rod-like member.
